(19) United States
(12) Patent Application Publication
(10) Pub. No.: US 2011/0165758 A1
(43) Pub. Date: Jul. 7, 2011

(54) METHOD FOR MAKING A STRUCTURE COMPRISING A STEP FOR IMPLANTING IONS IN ORDER TO STABILIZE THE ADHESIVE BONDING INTERFACE

(76) Inventors: Konstantin Bourdelle, Crolles (FR); Didier Landru, Champ Pres Froges (FR); Karine Landry, Grenoble (FR)

(21) Appl. No.: 12/997,835

(22) PCT Filed: Jul. 3, 2009
(86) PCT No.: PCT/EP09/58434

§ 371 Date: Dec. 13, 2010

(30) Foreign Application Priority Data
Aug. 6, 2008 (FR) 0855447

(51) Int. Cl. H01L 21/762

(52) U.S. Cl. 438/458; 257/E21.568

(57) ABSTRACT

The invention relates to a method for making a structure for use ion applications in the fields of electronics, optics or optoelectronics. The structure includes a thin layer of semiconducting material on a supporting substrate. The method includes bonding the thin layer onto the supporting substrate by molecular adhesion at a bonding interface to obtain a structure; implanting ions at the bonding interface to transfer atoms from the thin layer to transfer atoms between the thin layer and the supporting substrate or vice versa; and heat-treating the structure in order to stabilize the bonding interface.

The invention relates to a method for making a structure intended for applications in the fields of electronics, optics or optoelectronics, which comprises a thin layer of semiconducting material on a substrate.

Preferentially, this method is of the type including the steps of:
a) creating an embrittlement area in the thickness of a donor substrate;
b) adhesively bonding the donor substrate with a supporting substrate;
c) detaching the donor substrate, for example by detachment at the embrittlement area, or further by etching and/or grinding, in order to transfer a portion of the donor substrate onto the supporting substrate and to form the thin layer on the latter;
d) heat-treating the structure comprising the thin layer on the supporting substrate in order to stabilize the adhesive bonding interface between the thin layer and the supporting substrate.

But this method may also be of the kind in which:
application of step a) is omitted;
instead and in place of step c), the donor substrate is thinned by etching and/or grinding, in order to transfer a portion of the donor substrate onto the supporting substrate and to form the thin layer on the latter.

Methods of the aforementioned type are already known; these are for example methods of the Smart Cut (registered trade mark) type. More extensive details will be found relating to the Smart Cut process in the document Silicon-On-Insulator Technology: Materials to VLSI, 2nd Edition of Jean-Pierre Colinge at Kluwer Academic Publishers, p. 50 and 51.

With such methods, it is possible to advantageously make structures comprising a thin layer of semiconducting material on a supporting substrate and notably SOI (Semiconductor On Insulator) type structures, in which an insulating layer is inserted inbetween the thin layer and the supporting substrate.

The structures obtained by such methods are used for applications in the fields of microelectronics, optics and/or optoelectronics, the thin layer being typically used as an active layer for forming components.

Stabilization of the adhesive bonding interface between the thin layer and the supporting substrate proves to be necessary so that the obtained structure after detachment has mechanical and electrical properties which comply with the requirements and specifications of the fields of application of the invention.

The question is to notably ensure strong adhesion of the thin layer and of the supporting substrate. In the absence of such adhesion, there is a risk that the subsequent steps for forming electronic components lead to delamination of the thin layer at the adhesive bonding interface.

On this subject, it is noted that in the absence of a treatment at least aiming at reinforcing the adhesive bonding interface, immersion in a bath such as an HF bath for example, directly after detachment, of the structure formed according to a Smart Cut type method, leads to detachment of the thin layer at the periphery of the structure, over a radial extension of several microns, or even to total detachment of the thin layer.

Moreover, the quality of the adhesive bond at the adhesive bond interface is capable of changing the behavior of the carriers in the thin layer. In order to ensure satisfactory and reproducible electric performances, it is therefore required that the adhesive bonding interface be stabilized.

Partial solutions to the problem of stabilization of the adhesive bonding interface have been proposed. The latter recommend that a strong adhesive bond be made between the donor substrate and the supporting substrate, typically by providing thermal energy between the adhesive bonding and detachment steps, or even by carrying out before the adhesive bonding step a treatment for preparing either one and/or both of the surfaces to be adhesively bonded. But with these “pre-stabilization” treatments, it is not generally possible to obtain an interface with sufficient quality in terms of mechanical strength and/or electric performance.

In order to achieve real stabilization of the adhesive bonding interface between the thin layer and the supporting substrate, a heat treatment of the obtained structure after detachment and transfer of the thin layer from the donor substrate to the supporting substrate is typically carried out today.

More specifically, this treatment is annealing in an oven of the structure obtained after detachment, at a temperature of the order of 1,000 to 1,200° C., for one to two hours, depending on the nature of the materials of the structure (nature of the upper layer, of the supporting substrate and of the insulator). This is termed as stabilization annealing.

The defects possibly present at the adhesive bonding interface are visible on sample photographs of the section of a structure, taken with an electronic transmission microscope, possibly after a treatment aiming at making these defects better visible, as this is detailed in FR2903809.

Indeed, light areas are identified therein, which correspond to “open” spaces, i.e. distances between atoms which are larger than normal distances.

In any case, applying a temperature of the order of 1,000° C. to 1,200° C. in order to perfect the adhesive bonding interface has a certain number of constraints.

Thus, notably industrially, its application requires resorting to unconventional ovens.

Further, depending on the structure on which the adhesive bonding is carried out, the application of such a high temperature may damage it. This is the case when the materials of the upper layer and of the supporting substrate have different thermal expansion coefficients. This is also the case when one of the materials cannot be exposed to a too high temperature, such as for example germanium, for which the melting temperature is of the order of 900° C.

The present invention therefore aims at solving this problem by proposing a method of the kind mentioned above, with which a perfect adhesive bonding interface may be obtained, without having to resort to so high temperatures of stabilization annealing.

Thus, it relates to a method for making a structure notably intended for applications in the fields of electronics, optics or optoelectronics, which comprises a thin layer of semiconducting material on a supporting substrate, according to which:
a) said thin layer is adhesively bonded onto said supporting substrate by molecular adhesion;
b) said structure obtained in this way is heat-treated for stabilizing the adhesive bonding interface.

characterized by the fact that prior to step b), atoms from the thin layer are transferred to the supporting substrate and/or from the supporting substrate to the thin layer, by implanting ions at said interface.

With this treatment by implanting ions, it is somewhat proceeded with “damaging” of the region of the interface and with a rearrangement of the atoms.

This is expressed by better adhesive bonding of the interface, which requires lower stabilization annealing temperatures.

According to other advantageous and non-limiting features of this method:
prior to step a), an embrittlement area is created in the thickness of a semiconducting material donor substrate, so as to delimit at its surface, a thin layer and immediately after this step, the donor substrate is detached at said embrittlement line in order to individualize said thin layer;
in step a), a donor substrate in which said thin layer is integrated, is adhesively bonded on said supporting substrate and this donor substrate is thinned, notably by etching and/or grinding, until said thin layer is obtained;
said thin layer and said supporting substrate include a thickness of surface oxide so that said adhesive bonding interface is of the oxide-on-oxide type;
the method further comprises at least one step for thinning said thin layer, and it is proceeded with implanting ions after this thinning;
it is proceeded with said thinning by oxidation of the free surface of said thin layer and by removal of the thereby formed oxide;
it is proceeded with ion implantation by making use of energy, the value of which depends on the thickness of said thin layer, so that the major portion of the implanted ions are implanted in the region of the interface;
ions of at least one atomic species present at the interface are implanted;
ions of at least two atomic species are implanted, and the dosages of ions of each implanted species substantially observe the atomic stoichiometry present at said interface;
it is proceeded with co-implantation of ions of at least two atomic species;
it is proceeded with sequential implantations of ions of at least two atomic species;
it is proceeded with said implantation at room temperature;
it is proceeded with an implantation at a temperature of the order of 300° C.;
said step b) is carried out at a temperature at most equal to 1,200° C.;
said thin layer and supporting substrate are based on silicon, sapphire, gallium nitride or germanium;
said thin layer and supporting substrate are based on silicon and it is proceeded with co-implantation of silicon and oxygen ions, at an implantation dosage comprised between 10¹⁵at/cm² and 10¹⁶at/cm².

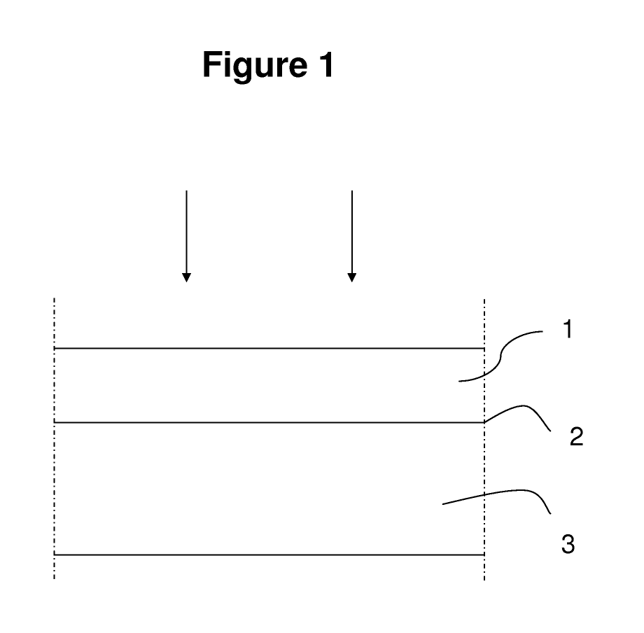

Other features and advantages of the present invention will become apparent upon reading the description which follows of a preferential embodiment. This description will be given with reference to the appended drawing wherein FIG. 1 is a partial sectional view of a structure according to the invention.

A thin layer, for example in silicon, provided with an oxide thickness is referenced therein as 1, and a supporting substrate, for example also in silicon with an oxide thickness, as 3. The oxidized surfaces of the layer 1 and of the supporting substrate 3 are put into contact and are adhesively bonded to each other by molecular adhesion, at an identified interface 2.

As stated above, the present invention may be considered as a mixing of the interface 2, by means of ion implantation, in order to damage the oxide/oxide interface in the case of this embodiment, and to rearrange the atoms in this region, so as ensure perfect cohesion between the layers 1 and 3 of the structure.

The parameters of this implantation are most particularly:
the mass of the ions;
the ion dosage;
the implantation temperature (the more the temperature is increased, the more a large dose may be implanted without damaging the material crossed);
the implantation energy (has mainly an influence on the implantation depth).

Preferably, the implanted ions are of the same nature as those present at the interface.

After the implantation, stabilization annealing is performed which allows oxygen to be diffused and the crystalline defects to be cured. A temperature of 800 or 900° C. may be sufficient for this purpose.

It is also possible to consider carrying out the implantation, not at room temperature but at a temperature of about 300° C., by which damaging may be limited and the duration of the stabilization annealing may be reduced.

This is particularly advantageous for the structures in which one of the materials may become damaged if it is subject to too high a temperature.

Finally, a relatively uniform oxide layer is obtained in which the interface is no longer distinct, because the structure has been perfectly reformed.

During implantation, it is sought not to damage too much the material (silicon) on either side of the oxide. Indeed, implantation will have the effect of amorphizing silicon, which will recrystallize upon stabilization annealing, but by letting defects remain, of the so-called “end of range”, i.e. end of travel, type.

It is specified that with view to the implantation, the thickness of the “top” thin layer should be sufficiently thin so that it may be crossed by the ions. If a thick “top” layer is desired, a solution is to carry out epitaxy after implantation. In this case the damaging of the material is moreover less critical.

In the case of an intermediate Si0₂ layer and of co-implantation of Si ions and oxygen ions, the ions will preferably be implanted in the same stoichiometric ratio as SiO₂ present at the interface. The implantation energy will be determined so that the ions are mainly distributed in the region of the interface.

The implantation may also be applied just after forming the thin layer. However, when the latter is thinned by successive oxidation of its free surface and removal of the thereby formed oxide in order to form an ultra-thin layer, the implantation may then be carried out after the last oxidization cycle/removal of the oxide.

### EXAMPLE 1

### Implantation of Si ions

An 501 structure (of the Si/SiO₂/Si type) obtained according to the Smart Cut™ method, is used, for which the adhesive bonding interface was formed by putting into contact the silicon oxide present on the side of the top thin layer and on the side of the support.

The total thickness of the oxide layer is 10 nm, whereas that of the top thin layer is from 300 to 400 nm. The implantation of Si ions takes place just after the detachment which occurs during the Smart Cut™ method of the thin layer.

It is proceeded with implantation of Si ions at an energy of 300 keV, at room temperature, and at a dose of 10¹⁵at/cm², which leads to onset of amorphization around the depth of the order of 340 mm. This should be sufficient according to the literature, for producing effective “mixing”.

This non-amorphizing implantation is followed by standard finishing steps, notably by annealing at a temperature below 1,200° C., for example comprised between 800° C. and 900° C.

An increase in the dosage of ions in order to obtain 3×10¹⁵at/cm² leads to the creation of an amorphous buried silicon layer, centered around the fine buried oxide layer. During the subsequent heat treatments and the steps for thinning the upper layer, this amorphous layer may recrystallize by epitaxy in the solid phase (briefly SPE, for “Solid Phase Epitaxy”). The “end of range” defects in the upper layer may be removed during the thinning of the thin layer. Those positioned below (i.e. in the supporting substrate), which will remain, themselves form a layer for trapping defects.

### EXAMPLE 2

### Co-Implantation of Si and O Ions at Room Temperature and at a Reduced Dosage

Structure of Si/SiO₂/sapphire type.

This structure is made in the following way; an SOI substrate having a 300 to 400 nm upper layer, a 100 nm buried oxide and an Si supporting substrate of the order of 700 microns, is oxidized in order to form a 100 nm surface oxide.

The oxidized upper layer of this substrate is put into contact with a sapphire substrate and the assembly is annealed at a low temperature (because of the thermal expansion coefficient difference which does not allow exposure of this assembly to too high a temperature), of the order of 300° C. to 600° C.

The silicon support as well as the buried oxide of the initial SOI substrate is removed by the successive grinding and etching steps.

Finally, the aforementioned Si/SiO₂/sapphire structure is then obtained. The adhesive bonding interface in this case is located between the oxide layer and the sapphire support.

The thickness of the oxide layer is 10 nm and that of the top thin layer is from 300 to 400 nm. The sapphire support has a thickness of several hundred microns.

Silicon and oxygen ions are implanted sequentially.

Si ions are implanted under an energy of about 300 keV.

O ions are implanted under an energy of about 180 keV.

The total implantation dose should be kept below the amorphization threshold, which is estimated to be 2.10¹⁵at/cm².

Respective doses of Si/O ions of the order of ½ are used in order to avoid distortions of the stoichiometry of the oxide layer.

The “standard” finishing steps are applied for completing the method, for example for thinning the top thin layer to its desired final thickness.

### EXAMPLE 3

### Implantation of Si Ions, Followed by Epitaxial Crystallization Induced by an Ion Beam (IBIEC), at High Temperature

Structure of the Si/SiO₂/Si type, similar to that of Example 1.

The thickness of the oxide layer is 10 nm and that of the thin layer from 300 to 400 nm.

The implantation takes place after detachment of the thin layer.

The Si ions are first implanted under an energy of 300 keV, at a dose of 2×10¹⁶at/cm². The implantation temperature is slightly below 200° C. It is estimated that this implantation creates amorphization of Si in the thin layer at a depth of about 100-150 nm.

Oxygen implantation is then carried out with an energy of about 180 keV, at 400° C. and at a dose of 4×10¹⁶at/cm², and this leads to complete IBIEC of the layer of amorphized Si, in order to reform a layer with satisfactory crystalline quality.

The standard finishing steps may be applied for perfecting the method.

It will be noted that the present invention is not limited to a method in which adhesive bonds apply one or two adhesive bonding layers in silicon oxide. In particular, it is applicable regardless of the nature of the materials present at the adhesive bonding interface.

For example these may be amorphous materials such as Si₃N₄ or crystalline materials.

This is notably the case when the thin layer exclusively consisting of a crystalline material is put into direct contact with the support, itself crystalline or polycrystalline.

1-15. (canceled)

16. A method for making a structure intended use in for applications in the fields of electronics, optics or optoelectronics, wherein the structure comprises a thin layer of semiconducting material on a supporting substrate, which method comprises:
bonding the thin layer onto the supporting substrate by molecular adhesion at a bonding interface to obtain a structure;
implanting ions at the bonding interface to transfer atoms from the thin layer to transfer atoms between the thin layer and the supporting substrate or vice versa; and
heat-treating the structure in order to stabilize the bonding interface.

17. The method of claim 16, which further comprises prior to bonding, creating an embrittlement area a semiconducting material donor substrate to delimit at its surface the thin layer and immediately thereafter detaching the donor substrate at the embrittlement area in order to individualize the thin layer.

18. The method of claim 16, which further comprises providing a donor substrate in which the thin layer is integrated, and thinning the donor substrate after bonding to obtain the thin layer.

19. The method of claim 18, wherein the donor substrate is thinned by etching or grinding.

20. The method of claim 16, wherein the thin layer and supporting substrate each include a surface oxide layer, so that the bonding interface is of the oxide-on-oxide type.

21. The method of claim 16, which further comprises at least one step for thinning the thin layer prior to the implanting of ions.

22. The method of claim 21, which further comprises oxidizing a free surface of the thin layer prior to thinning the layer by removing the oxidized surface.

23. The method of claim 16, which further comprises applying energy to the thin layer prior to the implanting of ions so that a major portion of the implanted ions are implanted at the bonding interface.

24. The method of claim 16, wherein the ions to be implanted include at least two different atomic species with the doses of ions of each implanted species selected to substantially observe atomic stoichiometry at the bonding interface.

25. The method of claim 24, wherein the ions of the at least two different atomic species are co-implanted.

26. The method of claim 24, wherein the ions of the at least two atomic species are implanted sequentially.

27. The method of claim 16, wherein the implanting is conducted at room temperature.

28. The method of claim 16, wherein the implanting is conducted at a temperature on the order of 300° C.

29. The method of claim 16, wherein the heat-treating is carried out at a temperature at most equal to 1,200° C.

30. The method of claim 16, wherein the thin layer and supporting substrate are based on silicon, sapphire, gallium nitride, or germanium.

31. The method of claim 30, wherein the thin layer and supporting substrate are based on silicon, and silicon and oxygen ions are co-implanted at an implantation dosage of between 10¹⁵at/cm² and 10¹⁶at/cm².
